(19) United States
(12) Patent Application Publication
(10) Pub. No.: US 2026/0214856 A1
(43) Pub. Date: Jul. 23, 2026

(54) ELECTRICAL CONNECTION UNIT

(71) Applicant: YAZAKI CORPORATION, Tokyo (JP)

(72) Inventors: Ryu Senoo, Kakegawa-shi (JP); Hirotaka Mukasa, Kakegawa-shi (JP)

(21) Appl. No.: 19/452,160

(22) Filed: Jan. 16, 2026

(30) Foreign Application Priority Data
Jan. 23, 2025 (JP) 2025-009675

(51) Int. Cl. H05K 7/20; H02G 3/16

(52) U.S. Cl. CPC H05K 7/2039; H02G 3/16

(57) ABSTRACT

An electrical connection unit includes a heat transfer portion, a first circuit, and a second circuit. The first circuit includes a bus bar and a first electronic component electrically connected to the bus bar and is disposed on a first side in a first direction with respect to the heat transfer portion. The second circuit includes a second electronic component and is disposed on a second side in the first direction with respect to the heat transfer portion.

### BACKGROUND OF THE INVENTION

### Field of the Invention

Embodiments of the present invention relate to an electrical connection unit.

Priority is claimed on Japanese Patent Application No. 2025-009675 filed in Japan on Jan. 23, 2025, the content of which is incorporated herein by reference.

### Description of Related Art

In the electrical connection unit, it is known that electronic components such as relays and resistors are mounted on a mounting surface of a housing.

### PRIOR ART DOCUMENT

### Patent Document

Patent Document 1: Japanese Unexamined Patent Application, First Publication No. 2018-113184

### SUMMARY OF THE INVENTION

Incidentally, the electrical connection unit may include a component that generates heat when energized. Due to such a component, it may be difficult to protect other components having low heat resistance.

One embodiment provides an electrical connection unit capable of heat protection of components.

An electrical connection unit according to one embodiment includes a heat transfer portion, a first circuit including a bus bar and a first electronic component electrically connected to the bus bar, the a first circuit being disposed on a first side in a first direction with respect to the heat transfer portion, and a second circuit including a second electronic component and disposed on a second side in the first direction with respect to the heat transfer portion.

An electrical connection unit according to one embodiment includes a heat transfer portion, a first circuit including a bus bar and a first electronic component electrically connected to the bus bar, the a first circuit being disposed on a first side in a first direction with respect to the heat transfer portion, and a relay bus bar including a first connection portion electrically connected to the first circuit, a second connection portion capable of being electrically connected to a second circuit including a second electronic component, the second circuit being disposed on a second side in the first direction with respect to the heat transfer portion, and an extension portion extending between the first connection portion and the second connection portion.

According to one embodiment, thermal protection of components is possible.

### BRIEF DESCRIPTION OF THE DRAWINGS

FIG. 1 is a perspective view illustrating an electrical connection unit according to an embodiment;

FIG. 2 is an exploded perspective view illustrating a metal cover and a first structure according to the embodiment;

FIG. 3 is an exploded perspective view illustrating the first structure, a relay bus bar, and part of an external connection bus bar according to the embodiment;

FIG. 4 is an exploded perspective view illustrating the electrical connection unit according to the embodiment;

FIG. 5 is a plan view illustrating the electrical connection unit according to an embodiment;

FIG. 6 is a plan view illustrating the electrical connection unit according to an embodiment as seen through a second cover;

FIG. 7 is a perspective view illustrating the relay bus bar according to the embodiment;

FIG. 8 is an enlarged perspective view of a portion VIII in FIG. 6 as further seen through a first cover;

FIG. 9 is a perspective view illustrating an electrical connection unit according to a modification example of the embodiment; and

FIG. 10 is a perspective view illustrating an electrical connection unit according to a modification example of the embodiment.

### DETAILED DESCRIPTION OF THE INVENTION

Hereinafter, embodiments will be described with reference to the drawings. In the following description, constitutions having the same or similar functions are denoted by the same reference numbers. Redundant descriptions of these constitutions may be omitted. The constitution to be described below does not limit the scope of the embodiment.

In the present disclosure, terms are defined as follows. The term “connection” is not limited to a mechanical connection and may include an electrical connection. That is, the term “connection” is not limited to a case where two elements that are connection targets are directly connected and may include a case where two elements that are connection targets are connected with another element interposed therebetween. The term “accommodation” is not limited to a case where the entire component is accommodated and may include a case where only part of the component is accommodated (a state in which the remaining part of the component protrudes). The term “cover” is not limited to a case where the entire target is covered and may include a case where only part of the target is covered. The term “facing” indicates that virtual projection images of two target objects overlap each other when viewed in a specific direction. That is, the term “facing” is not limited to a case where two target objects directly face each other and may include a case where two target objects face each other in a state in which another member exists between the two target objects. The term “orthogonal”, or “the same” may include “substantially orthogonal”, or “substantially the same”, respectively. The term “sheet-shaped” or “sheet” is not limited to a member having a thickness of 1 mm or more, and may be a member (so-called a film) having a thickness of less than 1 mm.

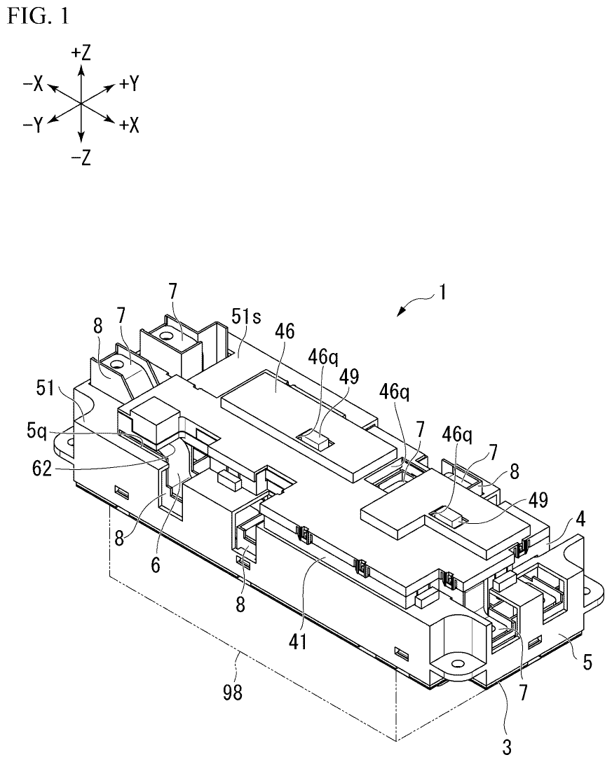

In the present disclosure, a +X direction, a −X direction, a +Y direction, a −Y direction, a +Z direction, and a −Z direction are defined as follows. As illustrated in FIG. 1, an X direction is one direction in a plane along a support surface 51s of a support portion 51 which will be described below. The +X direction is one direction of the X direction. The −X direction is the direction opposite to the +X direction. Hereinafter, the +X direction and the −X direction are simply referred to as the “X direction” in a case where they are not distinguished from each other. The Y direction is the direction intersecting (for example, orthogonal to) the X direction in a plane along the support surface 51s of the support portion 51 which will be described below. The +Y direction is one direction of the Y direction. The −Y direction is the direction opposite to the +Y direction. Hereinafter, the +Y direction and the −Y direction are simply referred to as the “Y direction” in a case where they are not distinguished from each other. The +Z direction and the −Z direction are directions intersecting (for example, orthogonal to) the X direction and the Y direction. The +Z direction is the direction in which the support surface 51s of the support portion 51 which will be described below faces. The −Z direction is the direction opposite to the +Z direction. Hereinafter, in a case where the +Z direction and the −Z direction are not distinguished, the directions will be simply referred to as a “Z direction”. The Z direction is an example of a “first direction”. The −Z direction side is an example of a “first side in the first direction”. The +Z direction side is an example of a “second side in the first direction”. The X direction is an example of a “second direction”. The Y direction is an example of a “third direction”.

Hereinafter, in a case where the X direction and the Y direction are not distinguished, the directions may be referred to as a “horizontal direction”. Hereinafter, the Z direction may be referred to as a “vertical direction”. Further, the +Z direction may be referred to as “upper”, and the −Z direction may be referred to as “lower”. However, these expressions are expressions for convenience of description, and do not limit the direction of gravity with respect to an electrical connection unit 1 (an installation orientation of the electrical connection unit 1).

### Embodiments

### 1. Constitution of Electrical Connection Unit

The electrical connection unit 1 is, for example, an in-vehicle device mounted on a vehicle such as an electric vehicle (EV), a hybrid electric vehicle (HEV), or a plug-in hybrid electric vehicle (PHEV). The electrical connection unit 1 is connected to a plurality of external devices present outside. The electrical connection unit 1 mediates connection between the plurality of external devices (hereinafter also referred to as a “product”). For example, the external devices may include a battery pack, a load, a charger, and the like. The battery pack is mounted on a vehicle. The load is a device including an inverter or the like for driving a motor of a vehicle driven by using power stored in the battery pack. The charger is a device for supplying power for charging the battery pack. The electrical connection unit 1 may be referred to as an “electrical connection box” or a “junction box”, for example. However, the electrical connection unit 1 is not limited to a box-shaped device.

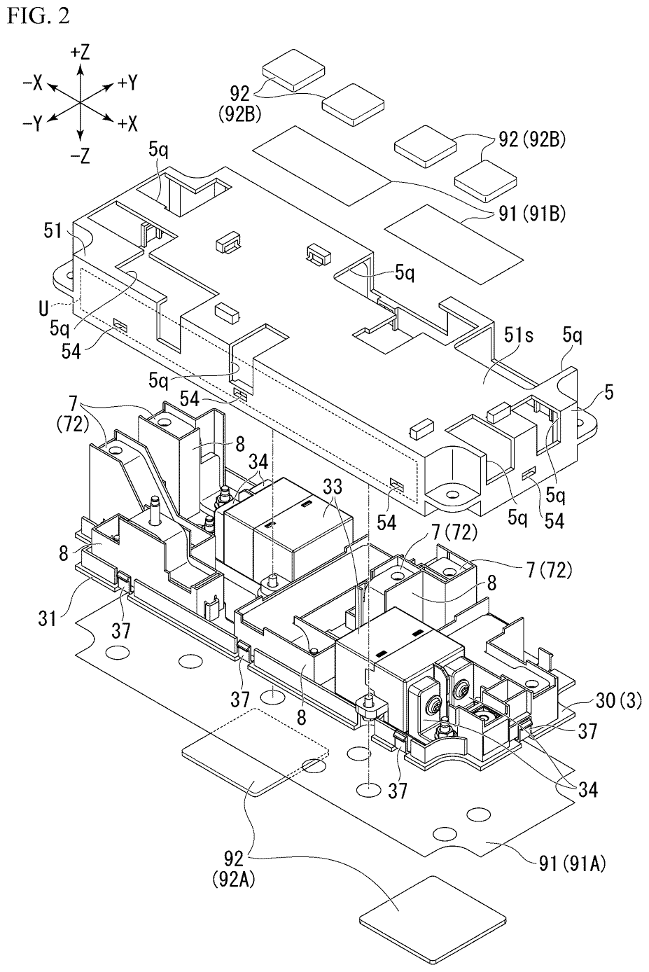

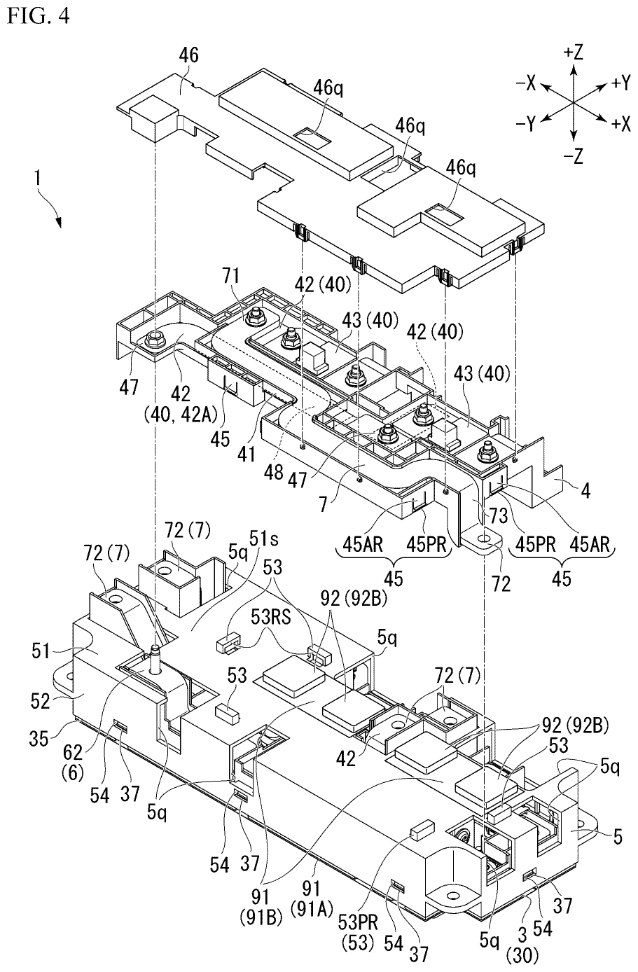

The electrical connection unit 1 includes a first structure 3, a second structure 4, a metal base 5, a relay bus bar 6, a plurality of external connection bus bars 7, and a plurality of auxiliary base members 8. The electrical connection unit 1 further includes an insulating sheet 91 and a heat transfer member 92 (see FIGS. 2 and 4). The second structure 4 is supported by the metal base 5. The second structure 4 is stacked on the first structure 3 with the metal base 5 interposed therebetween in the +Z direction. By this stacking, the electrical connection unit 1 has at least a two-story hierarchical structure. For example, the electrical connection unit 1 may be disposed in contact with a cooling surface of an external cooler 98 from the −Z side. The external cooler 98 may be, for example, a water jacket. The metal base 5 is an example of a “support”. The metal base 5 is an example of a “heat radiation structure”.

### 2. Constitution of First Structure

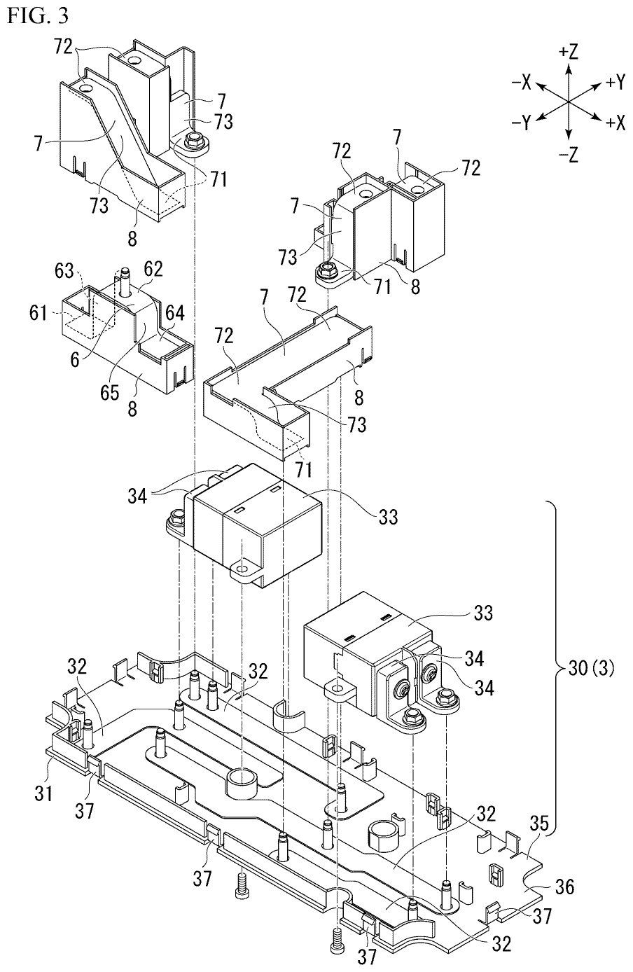

As illustrated in FIG. 2, the first structure 3 includes a first circuit 30. The first circuit 30 includes a routing board 31, a plurality of first electronic components 33, and a plurality of connection components 34. As illustrated in FIG. 3, the routing board 31 includes a plurality of bus bars 32 and a base plate 35. The base plate 35 is an example of a base member. Each bus bar 32 is an example of a first bus bar. The first structure 3 may be, for example, a unit included in a first floor portion of the two-story hierarchical structure of the electrical connection unit 1.

### First Electronic Component

Each first electronic component 33 is an important component for exerting a function of mediating connection between a plurality of external devices among the electronic components included in the electrical connection unit 1. Each first electronic component 33 may be, for example, an electronic component required for the electrical connection unit 1 in common for different products to which the electrical connection unit 1 is applied. The first electronic component 33 may be, for example, a component that generates heat when energized between the first electronic component 33 and the bus bar 32. The plurality of first electronic components 33 may include, for example, a relay (for example, a mechanical relay or a semiconductor relay). The plurality of first electronic components 33 may include, for example, a relay capable of switching between conduction and disconnection of the largest current among relays mounted on the electrical connection unit 1. Each first electronic component 33 is electrically connected to at least one bus bar 32 among the plurality of bus bars 32. Each first electronic component 33 may be electrically connected to the bus bar 32 via a pair of connection components 34, for example.

### Routing Board

The routing board 31 is a board for forming at least part of an energization path connected to the first electronic component 33. In the present disclosure, the “routing board” indicates a board-type routing structure. The “board-type” indicates a plate shape along one plane when viewed as a whole regardless of a fine shape. In the present disclosure, the “plate shape” is not limited to a completely flat shape, and may include a case where a fixing structure, a rib, or the like protruding in the Z direction is partially present. In the present embodiment, the routing board 31 has a plate shape formed in the X direction and the Y direction.

In the routing board 31, the plurality of bus bars 32 and the base plate 35 are integrated through insert molding. The routing board 31 is formed as a single member by insert-molding the bus bar 32 with the base plate 35. That is, the bus bar 32 is integrated with the base plate 35 without using a fastening member such as a screw or a bolt. Note that the routing board 31 may be formed by another structure instead of the insert molding.

### Base Plate

The base plate 35 is a holding member that integrally holds the plurality of bus bars 32 arranged in the horizontal direction at intervals. The base plate 35 is made of, for example, a synthetic resin and has an insulating property. The base plate 35 electrically insulates the plurality of bus bars 32 from each other. The base plate 35 includes a flat surface portion 36 and a plurality of claw portions 37. The base plate 35 is an example of a “base member”. The base plate 35 may be referred to as an “insulating substrate”.

The flat surface portion 36 is a portion formed in a plate shape in the base plate 35. The flat surface portion 36 has a plate shape formed in the horizontal direction. The flat surface portion 36 forms a main portion of the base plate 35. The flat surface portion 36 forms a base portion (insulating base portion) of the base plate 35. In the present embodiment, the flat surface portion 36 extends over the entire width in the X direction of the base plate 35 and over the entire width in the Y direction of the base plate 35 excluding four corner portions of the base plate 35. The first electronic component 33 is placed on the flat surface portion 36 from the +Z direction side of the flat surface portion 36. That is, the first electronic component 33 is disposed on the +Z direction side with respect to the flat surface portion 36. The plurality of claw portions 37 are located on the outer periphery of the flat surface portion 36. Each claw portion 37 protrudes from the flat surface portion 36 in the +Z direction.

### First Bus Bar

Each bus bar 32 is a routing member (electrical connection member) included in the routing board 31. Each bus bar 32 is, for example, a routing member which forms at least part of the energization path electrically connected to the first electronic component 33. Each bus bar 32 may be, for example, a routing member electrically connecting the first electronic component 33 to a second circuit 40 or an external device of the electrical connection unit 1. The bus bar 32 is made of a metal (for example, copper or a copper alloy) and has conductivity. At least part of each bus bar 32 is held by the base plate 35. The plurality of bus bars 32 may include, for example, portions disposed on the same plane.

At least part of each bus bar 32 has a plate shape formed in the horizontal direction. At least part of each bus bar 32 extends along the flat surface portion 36. In the present embodiment, each bus bar 32 has a plate shape formed in the horizontal direction over the entire length. The bus bar 32 is a member that forms an energization path in the horizontal direction.

### 3. Constitution of Second Structure

As illustrated in FIGS. 4 to 6, the second structure 4 includes the second circuit 40, a first cover 41, a plurality of lock portions 45, and a second cover 46. The second circuit 40 is supported by the support portion 51 (see FIG. 8). The second circuit 40 includes a plurality of second electronic components 43, and a plurality of bus bars 42. Each bus bar 42 is an example of a “second bus bar”. The second structure 4 may be, for example, a portion included in a second floor portion of the two-story hierarchical structure of the electrical connection unit 1.

### Second Electronic Component

Each second electronic component 43 is an electronic component for which a degree of freedom in design, component replacement, and the like according to a product to which the electrical connection unit 1 is applied are more likely to be required than the first electronic component 33. The second electronic component 43 may be, for example, an electronic component in which ease of routing is prioritized for each product to which the electrical connection unit 1 is applied and may be an electronic component in which a component position in the electrical connection unit 1 is likely to vary. The second electronic component 43 may be, for example, an electronic component of which component specifications are likely to vary for each product to which the electrical connection unit 1 is applied. The second electronic component 43 may be, for example, an electronic component which may or may not be mounted on the electrical connection unit 1 depending on component specifications of different products to which the electrical connection unit 1 is applied. The second electronic component 43 may be, for example, an electronic component that is likely to be replaced due to component deterioration, periodic maintenance, or the like of the electrical connection unit 1.

The second electronic component 43 may be, for example, various sensors (for example, a current sensor or a voltage sensor), a fuse, or a control circuit (for example, a micro controller unit (MCU), a microprocessor unit (MPU), or the like). The second electronic component 43 may be, for example, a relay other than a relay that controls conduction and disconnection of the largest current among a plurality of relays mounted on the electrical connection unit 1. Each of the plurality of second electronic components 43 is electrically connected to at least one bus bar 42 among the plurality of bus bars 42. The second electronic component 43 may include a signal connector 49.

The signal connector 49 is a connector through which a signal related to the second electronic component 43 can be input and output. For example, when the second electronic component 43 is a current sensor, the signal connector 49 may be able to transmit a detection signal related to the current flowing through the second electronic component 43 to the outside of the electrical connection unit 1. For example, when the second electronic component 43 is a fuse, the signal connector 49 may be able to transmit an alarm signal for informing the fusing of the second electronic component 43 to the outside of the electrical connection unit 1. For example, when the second electronic component 43 is a relay, the signal connector 49 may be able to receive a control signal for conduction and disconnection of the second electronic component 43 from the outside of the electrical connection unit 1.

### Second Bus Bar

Each bus bar 42 is a routing member for forming an energization path in the second circuit 40. Each bus bar 42 may form, for example, an energization path connected to the second electronic component 43. At least part of each bus bar 42 extends in the horizontal direction. The bus bar 42 is made of a metal (for example, copper or a copper alloy) and has conductivity. An end portion of each bus bar 42 may be connected to a terminal of the second electronic component 43, the relay bus bar 6, or another bus bar 42 by being fastened with a fastening member such as a screw or a bolt.

The plurality of bus bars 42 may include, for example, a bus bar 42A. For example, the bus bar 42A may three-dimensionally intersect the external connection bus bar 7. The bus bar 42A includes a pair of fourth connection portions 47 and a third extension portion 48. One of the pair of fourth connection portions 47 is fastened to a second connection portion 62 with a fastening member such as a screw or a bolt in an electrically connectable manner. The other fourth connection portion 47 of the pair of fourth connection portions 47 is electrically connected to the second electronic component 43 via the other bus bar 42. The other fourth connection portion 47 is fastened to a connection end of the other bus bar 42 with a fastening member such as a screw or a bolt. The third extension portion 48 extends over the pair of fourth connection portions 47. The third extension portion 48 is continuous with each of the pair of fourth connection portions 47. The third extension portion 48 is provided between the pair of fourth connection portions 47. The third extension portion 48 connects the pair of fourth connection portions 47. The third extension portion 48 extends while being bent. The third extension portion 48 extends in the +Y direction from the +Y direction side of one of the fourth connection portion 47 and extends in the +X direction while bending in the XY plane. The third extension portion 48 extends to the −X direction side of the other fourth connection portion 47 while having a step in the +Z direction in the middle of extending in the +X direction.

### First Cover and Second Cover

Each of the first cover 41 and the second cover 46 has a tray shape in which most (excluding part) of the outer periphery is erected. The first cover 41 and the second cover 46 are combined such that the directions in which the outer peripheries are erected face each other. The first cover 41 has a plurality of openings 41q. The first cover 41 covers the second circuit 40 from the −Z direction side of the second circuit 40 in a portion excluding the plurality of openings 41q. The second cover 46 has a plurality of openings 46q. The second cover 46 covers the second circuit 40 from the +Z direction side of the second circuit 40 in a portion excluding the plurality of openings 46q. The first cover 41 and the second cover 46 are combined to accommodate most of the second circuit 40 (for example, a portion of the bus bars 42 excluding a portion to be fastened to the relay bus bar 6 and the signal connector 49). For example, each of the first cover 41 and the second cover 46 may be separated from or in contact with the plurality of bus bars 42 and the plurality of second electronic components 43. Each of the first cover 41 and the second cover 46 may be made of, for example, a synthetic resin.

### Lock Portion

The plurality of lock portions 45 are located at ends of the second structure 4 on sides in the +X direction, the −X direction, the +Y direction, and the −Y direction. The plurality of lock portions 45 are integrally formed with the second cover 46. The lock portion 45 may be, for example, a snap-fit. The second structure 4 is fixed to the support portion 51 by the plurality of lock portions 45.

Each lock portion 45 includes an arm portion 45AR and a protrusion 45PR. The arm portion 45AR extends toward a first holding portion 53 which will be described below. The arm portion 45AR extends from the outer peripheral upper portion of the first cover 41 toward the first holding portion 53. The arm portion 45AR is deformable so as to warp in the horizontal direction from an orientation extending in the Z direction. The arm portion 45AR has a restoring force in a direction opposite to the deformation direction. The protrusion 45PR protrudes from the arm portion 45AR toward the first holding portion 53 in a direction intersecting the extending direction of the arm portion 45AR.

### 4. Constitution of Support (Heat Radiation Structure)

The metal base 5 includes the support portion 51, a peripheral wall 52, a plurality of the first holding portions 53, and a plurality of second holding portions 54. The metal base 5 has a plurality of openings 5q. Each opening 5q is open from the outside of the electrical connection unit 1 to an accommodation space U (see FIG. 2) which will be described below. The metal base 5 covers the first structure 3 from the +Z direction side of the first structure 3 excluding the plurality of openings 5q. At least part of the metal base 5 is made of a metal (for example, made of aluminum or aluminum alloy). The support portion 51, the peripheral wall 52, and the first holding portion 53 may be integrally formed using, for example, a metal material. The support portion 51 is an example of a heat transfer portion.

### Support Portion (Heat Transfer Portion)

The support portion 51 supports the second structure 4 from the −Z direction side of the second structure 4. The first circuit 30 is disposed on the −Z direction side with respect to the support portion 51. The second circuit 40 is disposed on the +Z direction side with respect to the support portion 51. The support portion 51 is interposed between the first circuit 30 and the second circuit 40. The support portion 51 has the support surface 51s facing in the +Z direction. The support surface 51s may be, for example, a flat surface.

The support portion 51 has heat conductivity. For example, the support portion 51 may have heat conductivity in the horizontal direction. At least part of the support portion 51 may be formed of, for example, a heat transfer material. At least part of the support portion 51 may be formed of, for example, a material having higher thermal conductivity than the base plate 35. At least part of the support portion 51 may be formed of, for example, a material having higher thermal conductivity than the first cover 41 or the second cover 46. At least part of the support portion 51 may be made of, for example, a metal (for example, made of aluminum or aluminum alloy).

### Peripheral Wall

The peripheral wall 52 extends in the −Z direction from the outer edge of the support portion 51 to the outer edge of the base plate 35. The peripheral wall 52 closes the outer periphery of a space sandwiched between the support portion 51 and the base plate 35 in a portion excluding the plurality of openings 5q and the plurality of second holding portions 54. The peripheral wall 52 covers at least the plurality of first electronic components 33 from sides in the +X direction, the −X direction, the +Y direction, and the −Y direction. With such a constitution, the plurality of first electronic components 33 are accommodated in the accommodation space U (see FIG. 2) defined by the metal base 5 and the routing board 31.

### Holding Portion

Each first holding portion 53 protrudes from the support portion 51 in the +Z direction. The first holding portion 53 has a recess 53RS. The recess 53RS is defined by being surrounded by an edge of the first holding portion 53 protruding in the horizontal direction. The recess 53RS is recessed in a direction in which the protrusion 45PR extends from the arm portion 45AR. When the first cover 41 is brought closer to the support portion 51 in the −Z direction, the protrusion 45PR climbs over the edge of the first holding portion 53 around the recess 53RS and is fitted into the recess 53RS. As a result, the second structure 4 is maintained in a state of being attached to the metal base 5.

Each second holding portion 54 is located closer to the −Z direction side of the peripheral wall 52. Each second holding portion 54 is caught by the tip end of the related claw portion 37. By this catch, the metal base 5 holds the base plate 35. The second holding portion 54 may be, for example, an opening that opens the peripheral wall 52 in the horizontal direction. Each second holding portion 54 is not limited to the opening and may be a recess recessed from the inner peripheral surface of the peripheral wall 52. On the other hand, each claw portion 37 may have any lock structure as long as it can be caught by the related second holding portion 54.

### Opening

Among the plurality of openings 5q, the opening 5q related to the relay bus bar 6 is disposed at a position where the first circuit 30 and the second circuit 40 can be electrically connected. The opening 5q related to the relay bus bar 6 may be disposed, for example, at a position where the relay bus bar 6 is exposed from the metal base 5 in the +Z direction. Among the plurality of openings 5q, the opening 5q related to the external connection bus bar 7 is disposed at a position where the external connection bus bar 7 can pass between the −Z direction side of the support portion 51 and the +Z direction side of the support portion 51.

### 5. Constitution of Relay Bus Bar

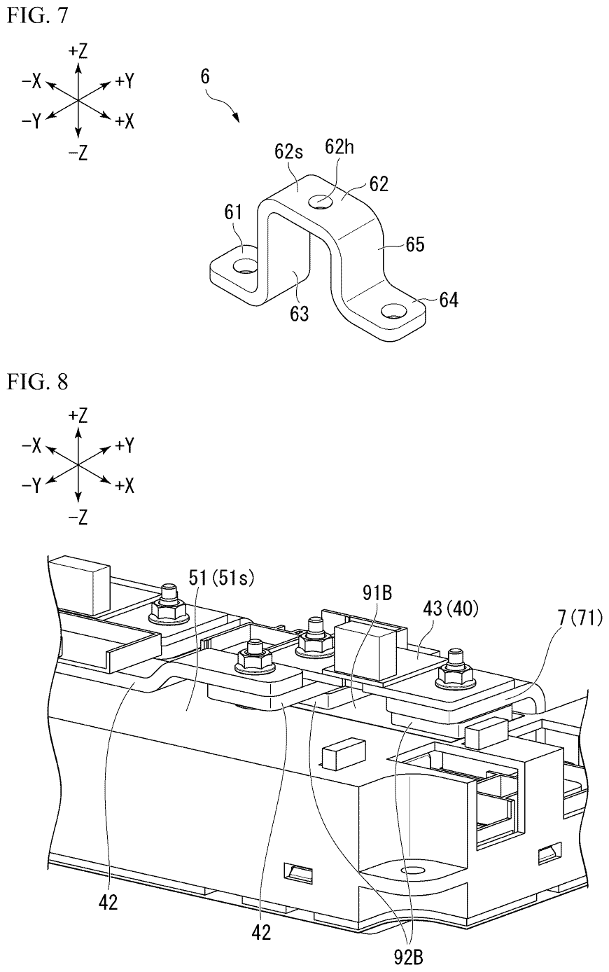

The relay bus bar 6 is electrically connected to the bus bar 32 and the bus bar 42 so as to relay the bus bar 32 and the bus bar 42. The relay bus bar 6 is a member that forms an energization path in the vertical direction. As illustrated in FIGS. 3 and 7, the relay bus bar 6 includes a first connection portion 61, the second connection portion 62, a first extension portion 63, a third connection portion 64, and a second extension portion 65. As will be described below, for example, part of the relay bus bar 6 may protrude from the support surface 51s toward the +Z direction side (see FIG. 4). The relay bus bar 6 may be connected, for example, to the second circuit 40 on the +Z direction side with respect to the support surface 51s. The first extension portion 63 is an example of an “extension portion”.

### First Connection Portion

The first connection portion 61 is a portion of the relay bus bar 6 continuously extending in the −X direction from the −Z direction side of the first extension portion 63. The first connection portion 61 is electrically connected to the bus bar 32. For example, the first connection portion 61 may be fastened to one end of the bus bar 32 with a fastening member such as a screw or a bolt in an electrically connectable manner.

### Second Connection Portion

The second connection portion 62 is disposed on the +Z direction side with respect to the first connection portion 61. The second connection portion 62 is a portion of the relay bus bar 6 continuously extending in the +X direction from the +Z direction side of the first extension portion 63.

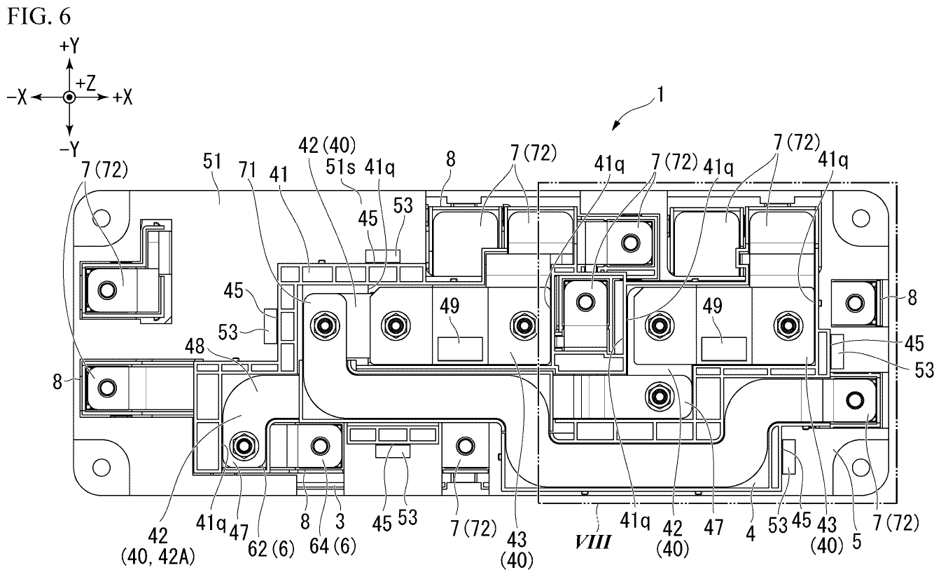

The second connection portion 62 can be electrically connected to the second circuit 40. The second connection portion 62 is exposed toward the second structure 4. For example, the second connection portion 62 may be exposed in the +Z direction from the opening 5q (see FIGS. 1 and 6). For example, the second connection portion 62 may slightly protrude from the metal base 5 in the +Z direction (see FIGS. 1 and 4). However, the second connection portion 62 may be flush with the support portion 51 on the +Z direction side.

The second connection portion 62 is electrically connected to the bus bar 42 (see FIG. 6). For example, the second connection portion 62 may be fastened to one end of the bus bar 42 with a fastening member such as a screw or a bolt in an electrically connectable manner. For example, the second connection portion 62 may have a flat surface 62s that is capable of coming into contact with the bus bar 42 and faces in the +Z direction. For example, the second connection portion 62 may have a fastening hole 62h through which a fastening member such as a screw or a bolt is inserted. The fastening hole 62h may pass through the second connection portion 62 in the Z direction, for example.

### First Extension Portion

The first extension portion 63 extends over the first connection portion 61 and the second connection portion 62. The first extension portion 63 is provided between the first connection portion 61 and the second connection portion 62. The first extension portion 63 connects the first connection portion 61 and the second connection portion 62. The first extension portion 63 extends continuously from the +X direction side of the first connection portion 61 extending in the X direction. The first extension portion 63 extends in the +Z direction while gently bending in the +Z direction from the first connection portion 61. The first extension portion 63 extends continuously from the −X direction side of the second connection portion 62 extending in the X direction. The first extension portion 63 extends in the −Z direction while gently bending in the −Z direction from the second connection portion 62.

### Third Connection Portion

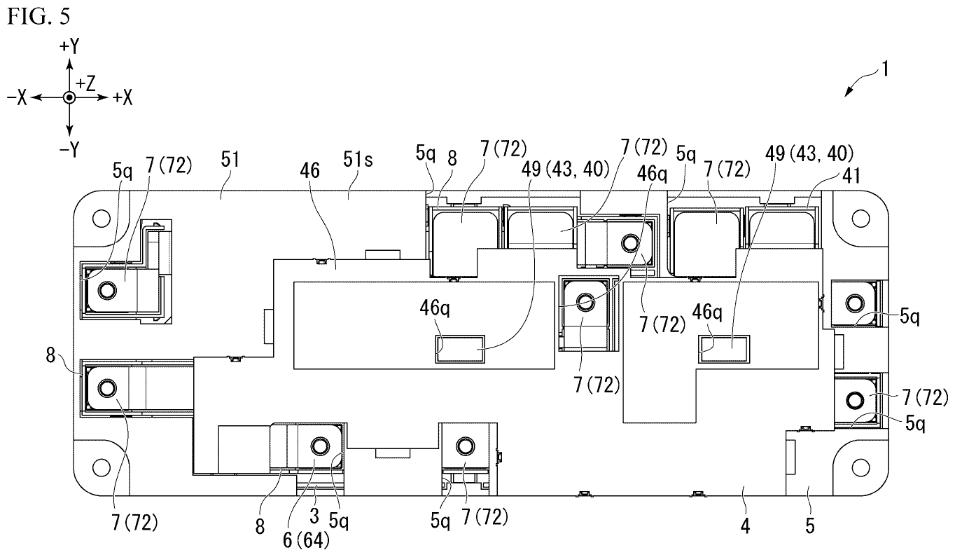

The third connection portion 64 is a portion of the relay bus bar 6 extending in the +X direction from the −Z direction side of the second extension portion 65. For example, the third connection portion 64 may be exposed in the +Z direction from the second structure 4 and the metal base 5 (see FIG. 5). The third connection portion 64 is electrically connected to a device outside the electrical connection unit 1. For example, the third connection portion 64 may be fastened to one end of a routing member (for example, a bus bar) extending from a device outside the electrical connection unit 1 with a fastening member such as a screw or a bolt in an electrically connectable manner to each other.

### Second Extension Portion

The second extension portion 65 extends over the second connection portion 62 and the third connection portion 64. The second extension portion 65 is provided between the second connection portion 62 and the third connection portion 64. The second extension portion 65 connects the second connection portion 62 and the third connection portion 64. The second extension portion 65 extends continuously from the +X direction side of the second connection portion 62 extending in the X direction. The second extension portion 65 extends in the −Z direction while gently bending in the −Z direction from the second connection portion 62. The second extension portion 65 extends continuously from the −X direction side of the third connection portion 64 extending in the X direction. The second extension portion 65 extends in the +Z direction while gently bending in the +Z direction from the third connection portion 64.

### 6. Constitution of External Connection Bus Bar

The plurality of external connection bus bars 7 are bus bars for electrically connecting an external device to the first circuit 30 or the second circuit 40. As illustrated in FIGS. 3 and 4, each external connection bus bar 7 includes a fifth connection portion 71, a sixth connection portion 72, and a fourth extension portion 73. Like the fifth connection portion 71 or the sixth connection portion 72 which will be described below, for example, some bus bar portions of the external connection bus bar 7 may be disposed on the +Z direction side with respect to the support portion 51.

### Fifth Connection Portion

The fifth connection portion 71 is a portion of the external connection bus bar 7 extending in the horizontal direction from one end of the fourth extension portion 73. The fifth connection portion 71 is electrically connected to the bus bar 32 or the bus bar 42. For example, the fifth connection portion 71 may be fastened to one end of the bus bar 32 or the bus bar 42 with a fastening member such as a screw or a bolt in an electrically connectable manner. In at least one external connection bus bar 7 of the external connection bus bars 7, the fifth connection portion 71 may be disposed, for example, on the +Z direction side with respect to the support surface 51s (see FIG. 4).

### Sixth Connection Portion

The sixth connection portion 72 can be electrically connected to a routing member (for example, a bus bar) extending from an external device. The sixth connection portion 72 is disposed on the +Z direction side or the −Z direction side with respect to the fifth connection portion 71. The sixth connection portion 72 is a portion of the external connection bus bar 7 extending in the horizontal direction from the other end of the fourth extension portion 73. In at least some external connection bus bars 7 of the external connection bus bars 7, the sixth connection portion 72 may be disposed, for example, on the +Z direction side with respect to the support surface 51s (see FIG. 4).

As illustrated in FIG. 5, the sixth connection portion 72 is exposed in the +Z direction from the opening 5q of the metal base 5. For example, the sixth connection portion 72 may be exposed in the +Z direction from the second structure 4 and the metal base 5 so as to be electrically connected to a routing member (for example, a bus bar) extending from an external device.

Some of the sixth connection portions 72 may be fastened to a routing member (for example, a bus bar) extending from an external device with a fastening member such as a screw or a bolt, for example. Some of the sixth connection portions 72 may be connected to a routing member (for example, a bus bar) extending from an external device by welding, for example.

### Fourth Extension Portion

As shown in FIGS. 3 and 4, the fourth extension portion 73 extends over the fifth connection portion 71 and the sixth connection portion 72. The fourth extension portion 73 is provided between the fifth connection portion 71 and the sixth connection portion 72. The fourth extension portion 73 connects the fifth connection portion 71 and the sixth connection portion 72. The fourth extension portion 73 extends continuously from one end of the fifth connection portion 71 extending in the horizontal direction. The fourth extension portion 73 extends in the +Z direction (or the −Z direction) while gently bending in the +Z direction (or the −Z direction) from the fifth connection portion 71. The fourth extension portion 73 extends continuously from one end of the sixth connection portion 72 extending in the horizontal direction. The fourth extension portion 73 extends in the −Z direction (or the +Z direction) while gently bending in the −Z direction (or the +Z direction) from the sixth connection portion 72.

### 7. Constitution of Auxiliary Base Member

The plurality of auxiliary base members 8 are support members that assist three-dimensional routing of various bus bars. Each of the plurality of auxiliary base members 8 supports the relay bus bar 6 from the −Z direction side of the relay bus bar 6 or the external connection bus bar 7 from the −Z direction side of the external connection bus bar 7. The auxiliary base member 8 may support, for example, two external connection bus bars 7. The auxiliary base member 8 is disposed between the routing board 31 and the related bus bar among the relay bus bar 6 and the external connection bus bar 7 in the Z direction. The auxiliary base member 8 is made of, for example, a synthetic resin and has an insulating property. The auxiliary base member 8 is an example of an “auxiliary support” or a “third support”.

### 8. Constitution of Insulating Sheet

A plurality of insulating sheets 91 are insulating members for insulating the first circuit 30 and the second circuit 40. As illustrated in FIG. 2, each insulating sheet 91 has a sheet shape formed in the horizontal direction. Each insulating sheet 91 has an insulating property. Each insulating sheet 91 is made of, for example, a synthetic resin such as polyester or polyimide. The plurality of insulating sheets 91 include a first insulating sheet 91A and a pair of second insulating sheets 91B.

The first insulating sheet 91A is disposed on the −Z direction side of the first circuit 30. For example, the first insulating sheet 91A is disposed so as to be in contact with a surface on the −Z direction side of the routing board 31. The first insulating sheet 91A may be disposed, for example, between the routing board 31 and a pair of first heat transfer members 92A which will be described below.

As illustrated in FIG. 4, the pair of second insulating sheets 91B are disposed on the −Z direction side of the second circuit 40. The pair of second insulating sheets 91B faces the support surface 51s, for example. The pair of second insulating sheets 91B are disposed so as to be in contact with the support surface 51s, for example. Each second insulating sheet 91B may be disposed, for example, between the support surface 51s and a pair of related second heat transfer members 92B among two pairs of second heat transfer members 92B which will be described below.

### 9. Constitution of Heat Transfer Member

A plurality of heat transfer members 92 are members for transferring heat (Joule heat) generated by the first circuit 30 and the second circuit 40 at the time of energization to the outside of the first circuit 30 and the second circuit 40. Each heat transfer member 92 is, for example, a heat transfer sheet (for example, a thermally conductive silicone sheet) having elasticity. Each heat transfer member 92 may be made of, for example, a material having higher thermal conductivity than the base plate 35. However, each heat transfer member 92 is not limited to the above example, and may be a heat transfer member made of a thermally conductive gel or another material. As illustrated in FIG. 2, the plurality of heat transfer members 92 include the pair of first heat transfer members 92A and the two pairs of second heat transfer members 92B.

The pair of first heat transfer members 92A is disposed between the cooling surface (see FIG. 1) of the external cooler 98 and the first insulating sheet 91A. For example, each first heat transfer member 92A may be disposed at a position overlapping the related first electronic component 33 when viewed in the Z direction.

As illustrated in FIG. 4, the two pairs of second heat transfer members 92B are disposed between the pair of second insulating sheets 91B and the second circuit 40. Each pair of the two pairs of second heat transfer members 92B faces a surface of the related second insulating sheet 91B which faces in the +Z direction. Each pair of the two pairs of second heat transfer members 92B faces a surface of the related second electronic component 43 which faces in the −Z direction. As shown in FIG. 8, each pair of second heat transfer members 92B may be disposed at a position overlapping the related second electronic component 43 when viewed in the Z direction. For example, each second electronic component 43 may be placed on the support portion 51 via the bus bar 42 or the external connection bus bar 7, the pair of second heat transfer members 92B, and the second insulating sheet 91B.

### 10. Advantages Related to Heat Transfer Portion

### First Advantage: Advantage Related to Heat Transfer Portion

According to the electrical connection unit 1 of the present embodiment, the first circuit 30 including the first electronic component 33 electrically connected to the bus bar 32 is disposed on the −Z direction side with respect to the support portion 51. On the other hand, the second circuit 40 including the second electronic component 43 is disposed on the +Z direction side with respect to the support portion 51. With these constitutions, heat generated by the first electronic component 33 is transferred to the support portion 51 to be radiated. Due to the heat radiation, the heat is less likely to be transferred to the second electronic component 43. Therefore, the component can be protected from the generated heat.

### Second Advantage

According to the electrical connection unit 1 of the present embodiment, the second electronic component 43 has a lower heat-resistant temperature than the first electronic component 33. On the other hand, due to the heat radiation, the heat generated by the first electronic component 33 is less likely to be transferred to the second electronic component 43. Therefore, the component having a low heat-resistant temperature can be protected from the generated heat.

### Third Advantage

According to the electrical connection unit 1 of the present embodiment, the support portion 51 is made of a metal. With such a constitution, the support portion 51 has a characteristic of easily transferring heat. Therefore, it is easy to protect the component from the generated heat.

### Fourth Advantage

According to the electrical connection unit 1 of the present embodiment, the support portion 51 supports the second circuit 40. According to this constitution, the first circuit 30 and the second circuit 40 can be stacked in a space-saving manner. Therefore, the electrical connection unit 1 can be miniaturized.

### Fifth Advantage

According to the electrical connection unit 1 of the present embodiment, the relay bus bar 6 can connect the first circuit 30 and the second circuit 40. With such a relay bus bar 6, components to be avoided from the heat generated by the first electronic component 33 can be freely aggregated in the second circuit 40 as the second electronic component 43. Therefore, it is easy to protect the component from the generated heat.

### Sixth Advantage

According to the electrical connection unit 1 of the present embodiment, the first electronic component 33 includes the relay. With this constitution, among the electronic components included in the electrical connection unit 1, the relay, which is a component that easily generates heat, can be disposed on the −Z direction side with respect to the support portion 51. Therefore, it is easy to protect the component from the generated heat.

### Seventh Advantage

According to the electrical connection unit 1 of the present embodiment, the second electronic component 43 includes a sensor, a fuse, or a control circuit. With this constitution, among the electronic components included in the electrical connection unit 1, a sensor, a fuse, or a control circuit having relatively low heat resistance can be disposed on the +Z direction side with respect to the support portion 51. Therefore, it is easy to protect the component from the generated heat.

### 11. Advantage Related to Layout

### Eighth Advantage

According to the electrical connection unit 1 of the present embodiment, the first circuit 30 is disposed on a side in the −Z direction with respect to the support portion 51. On the other hand, according to the electrical connection unit 1, the second circuit 40 is disposed on the +Z direction side with respect to the support portion 51. With these constitutions, components whose layout may be changed according to a product to be connected to the electrical connection unit 1 and peripheral circuits thereof can be aggregated in the second circuit 40. This aggregation makes it easy to change the layout regardless of the first circuit 30. Therefore, according to the electrical connection unit 1, it is easy to apply the electrical connection unit to different products.

For example, even if the presence or absence of an optional component among the plurality of second electronic components 43 in the second circuit 40 occurs according to the product to be connected to the electrical connection unit 1, the second circuit 40 can be changed according to the presence or absence of the optional component without changing the first circuit 30.

For example, even if a change of the optional component among the plurality of second electronic components 43 in the second circuit 40 occurs according to the product to be connected to the electrical connection unit 1, the second circuit 40 can be changed according to the changed optional component without changing the first circuit 30.

In addition, among the electronic components included in the electrical connection unit 1, components that require component maintenance and components that are highly likely to be replaced can be collected in the second circuit 40. Therefore, according to the electrical connection unit 1, it is easy to perform maintenance of the electrical connection unit.

### Ninth Advantage

According to the electrical connection unit 1 of the present embodiment, the relay bus bar 6 connects the first circuit 30 and the second circuit 40. With such a relay bus bar 6, components to be aggregated and peripheral circuits thereof can be freely aggregated in the second circuit 40. Therefore, it is easy to change the layout regardless of the first circuit 30.

### Tenth Advantages

According to the electrical connection unit 1 of the present embodiment, the base plate 35 is disposed on the −Z direction side with respect to the support portion 51. In addition, the first circuit 30 includes the bus bar 32 and the first electronic component 33. In addition, the second circuit 40 includes the bus bar 42 and the second electronic component 43. With these constitutions, regardless of the presence of the bus bar 32, the first electronic component 33, and the base plate 35, the layout of the bus bar 42 and the second electronic component 43 can be easily changed. Therefore, according to the electrical connection unit 1, it is easy to apply the electrical connection unit to different products.

### Eleventh Advantage

According to the electrical connection unit 1 of the present embodiment, the second electronic component 43 includes a sensor, a fuse, or a control circuit. With this constitution, a circuit related to a sensor, a fuse or a control circuit, which is often changed according to the product to be connected to the electrical connection unit 1, can be disposed on the +Z direction side with respect to the support portion 51. Therefore, according to the electrical connection unit 1, it is easy to apply the electrical connection unit to different products.

### 12. Advantages Related to Degree of Freedom in Routing

### Twelfth Advantage

According to the electrical connection unit 1 of the present embodiment, the first circuit 30 is disposed on a side in the −Z direction with respect to the support portion 51. On the other hand, according to the electrical connection unit 1, the second circuit 40 including the bus bar 42 is disposed on the +Z direction side with respect to the support portion 51. With these constitutions, regardless of the first circuit 30, the direction and length of the bus bar 42 can be freely changed according to the product to be connected to the electrical connection unit 1. With this degree of freedom, it is easy to cope with the position of the connection portion of the product to be connected. Therefore, according to the electrical connection unit 1, it is easy to apply the electrical connection unit to different products.

### Thirteenth Advantage

According to the electrical connection unit 1 of the present embodiment, the relay bus bar 6 connects the first circuit 30 and the second circuit 40. With such a relay bus bar 6, bus bars having a possibility of changing the direction and the length can be freely aggregated in the second circuit 40. Therefore, regardless of the first circuit 30, it is easy to cope with the position of the connection portion of the product to be connected. Therefore, according to the electrical connection unit 1, it is easy to apply the electrical connection unit to different products.

### Fourteenth Advantage

According to the electrical connection unit 1 of the present embodiment, the second electronic component 43 includes a sensor, a fuse, and a control circuit. With this constitution, the positions of the sensor, the fuse, and the control circuit, which are components relatively close to the connection portion of the product to be connected, among the electronic components included in the electrical connection unit 1, can be freely changed. With this degree of freedom, it is easy to cope with the position of the connection portion of the product to be connected. Therefore, according to the electrical connection unit 1, it is easy to apply the electrical connection unit to different products.

### Fifteenth Advantage

According to the electrical connection unit 1 of the present embodiment, part of the bus bar portion of the external connection bus bar 7 is disposed on a side in the +Z direction with respect to the support portion 51. With these constitutions, regardless of the first circuit 30, the direction and length of the external connection bus bar 7 can be freely changed according to the product to be connected to the electrical connection unit 1. With this degree of freedom, it is easy to cope with the position of the connection portion of the product to be connected. Therefore, according to the electrical connection unit 1, it is easy to apply the electrical connection unit to different products.

### Modification Examples

Next, several modification examples will be described. Note that constitutions other than those which will be described below in each modification example are the same as the constitutions of the above-described embodiment.

### First Modification Example

In the above-described embodiment, since the second structure 4 is stacked on the first structure 3, the electrical connection unit 1 has a two-story structure. However, the electrical connection unit 1 may be configured in any manner as long as it has a hierarchical structure. As a modification example, the electrical connection unit 1 may have a three-story structure, a four-story structure, or the like exceeding a two-story structure by further including a third structure, a fourth structure, or the like.

### Second Modification Example

In the above-described embodiment, the second structure 4 is stacked on the first structure 3 with the metal base 5 interposed therebetween. However, the electrical connection unit 1 may be configured in any manner as long as it has a hierarchical structure. As a modification example, in the electrical connection unit 1, the second structure 4 may be stacked on the first structure 3 with another structure in addition to the metal base 5 interposed therebetween.

### Third Modification Example

In the above-described embodiment, the first circuit 30 includes the routing board 31. However, the routing structure may be any routing structure as long as it forms at least part of the energization path connected to the first electronic component 33. As a modification example, the first circuit 30 may not include the base plate 35. As another modification example, the first circuit 30 may include a base member having a block shape, a box shape, or the like instead of the base plate 35.

### Fourth Modification Example

In the above-described embodiment, the electrical connection unit 1 includes the relay bus bar 6. However, the electrical connection unit 1 may include any relay routing member as long as it can connect the first circuit 30 and the second circuit 40. As a modification example, the electrical connection unit 1 may include a relay electric wire instead of the relay bus bar 6.

### Fifth Modification Example

In the above-described embodiment, the first circuit 30 includes the bus bar 32. However, the first circuit 30 may include any routing member as long as it can form at least part of the energization path electrically connected to the first electronic component 33. As a modification example, the first circuit 30 may include an electric wire instead of the bus bar 32.

### Sixth Modification Example

In the above-described embodiment, the second circuit 40 includes the bus bar 42. However, the second circuit 40 may include any routing member as long as it can form at least part of the energization path electrically connected to the first electronic component 33. As a modification example, the second circuit 40 may include an electric wire instead of the bus bar 32 as the routing member.

### Seventh Modification Example)

In the above-described embodiment, the electrical connection unit 1 includes the external connection bus bar 7. However, the electrical connection unit 1 may include any routing member as long as it can electrically connect the external device and the first circuit 30 or the second circuit. As a modification example, the electrical connection unit 1 may include an external connection electric wire instead of the external connection bus bar 7.

### Eighth Modification Example

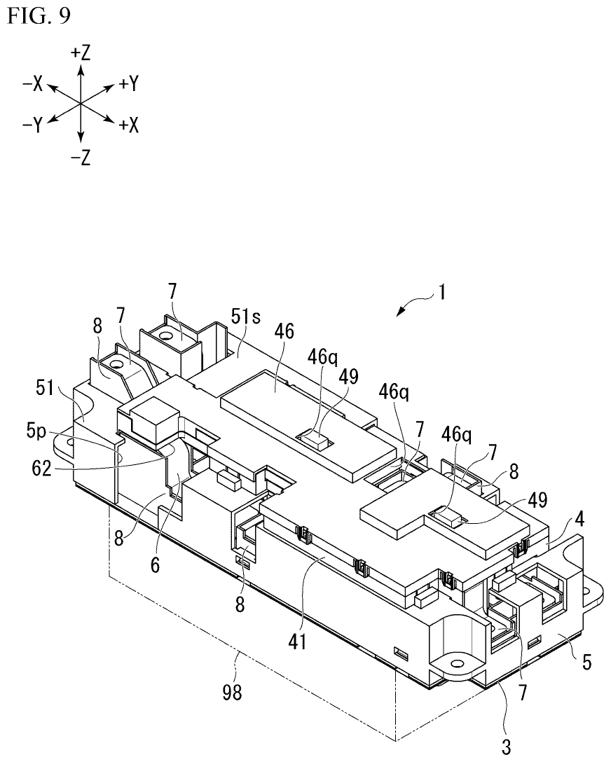

In the above-described embodiment, the second connection portion 62 is exposed from the opening 5q in the +Z direction. However, the second connection portion 62 may be configured in any manner as long as it can be electrically connected to the second circuit 40. As a modification example, as illustrated in FIG. 9, the second connection portion 62 may be exposed from a notch 5p in the +Z direction. The second connection portion 62 may slightly protrude from the metal base 5 in the +Z direction, for example, such that the relay bus bar 6 passes through the notch 5p. However, the second connection portion 62 may be flush with the metal base 5 on the +Z direction side.

### Ninth Modification Example

In the above-described embodiment, the second circuit 40 includes the bus bar 42 connected to the second electronic component 43. However, the second circuit 40 may include any routing member as long as it can be routed on the +Z direction side with respect to the support portion 51. As a modification example, the second circuit 40 may include, in the external connection bus bar 7, a bus bar portion disposed on the +Z direction side with respect to the support portion 51, the bus bar portion being electrically connected to the second electronic component 43. As another modification example, the second circuit 40 may include, in the external connection bus bar 7, a bus bar portion disposed on the +Z direction side with respect to the support portion 51, the bus bar portion being not electrically connected to the second electronic component 43.

### Tenth Modification Example

In the above-described embodiment, the second circuit 40 is supported by the support portion 51 of the metal base 5. However, the electrical connection unit 1 may be configured in any manner as long as the components to be avoided from the heat generated by the first electronic component 33 can be aggregated in the second circuit 40. As a modification example, in the electrical connection unit 1, the support portion 51 may not support the second circuit 40.

### Eleventh Modification Example

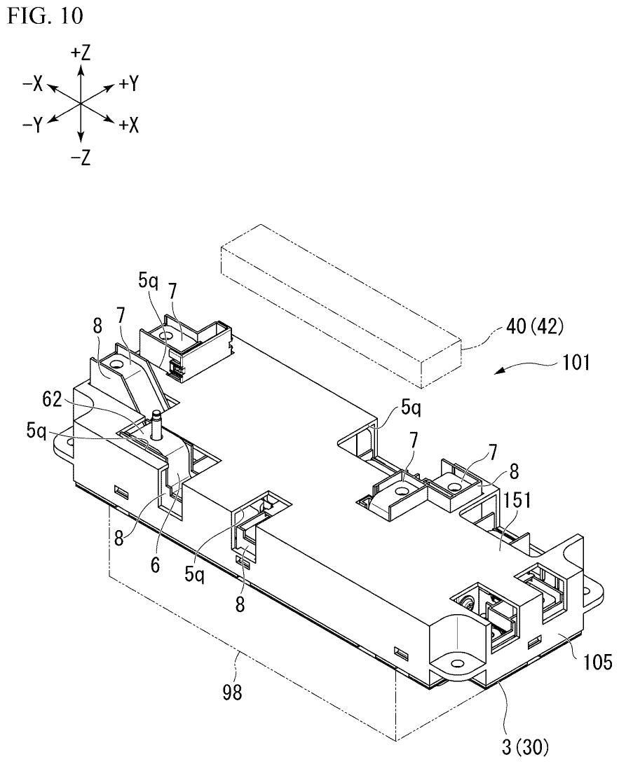

In the above-described embodiment, the second circuit 40 is supported by the support portion 51 of the metal base 5. However, the electrical connection unit 1 may be configured in any manner as long as the components to be avoided from the heat generated by the first electronic component 33 can be aggregated in the second circuit 40. As a modification example, the electrical connection unit 1 may be an electrical connection unit 101 as illustrated in FIG. 10. In contrast to the electrical connection unit 1, the electrical connection unit 101 includes a heat radiation structure 105 having a heat transfer portion 151 that does not support the second circuit 40, instead of the metal base 5 (having the support portion 51 that supports the second circuit 40). Similarly to the electrical connection unit 1, the electrical connection unit 101 includes the first structure 3, the relay bus bar 6, and the external connection bus bar 7 (excluding part thereof). In addition, similarly to the metal base 5, the heat radiation structure 105 has the plurality of openings 5q. In addition, the relay bus bar 6 includes the second connection portion 62 capable of being electrically connected to the bus bar 42 of the second circuit 40 disposed on the +Z side with respect to the heat transfer portion 151. The second circuit 40 and the second connection portion 62 may be capable of being fastened to each other so as to be capable of being electrically connected.

Even with the constitutions of these modification examples, the components to be avoided from the heat generated by the first electronic component 33 can be aggregated in the second circuit 40. Therefore, it is easy to protect the component from the generated heat.

In addition, even with the constitutions of these modification examples, regardless of the first circuit 30, the direction and length of the bus bar 42 can be freely changed. With this degree of freedom, it is easy to cope with the position of the connection portion of the product to be connected. Therefore, according to the electrical connection unit 1, 101, it is easy to apply the electrical connection unit to different products.

In addition, even with the constitutions of these modification examples, components whose layout may be changed according to a product to be connected to the electrical connection unit 1, 101 and peripheral circuits thereof can be aggregated in the second circuit 40. This aggregation makes it easy to change the layout regardless of the first circuit 30. Therefore, according to the electrical connection unit 1, 101, it is easy to apply the electrical connection unit to different products.

Several embodiments and modification examples have been described above. However, the embodiments and the modification examples are not limited to the examples described above. For example, a plurality of embodiments may be realized in combination with each other.

### REFERENCE SIGNS LIST

1 Electrical connection unit
3 First structure
4 Second structure
5 Metal base (support, heat radiation structure)
5q Opening
6 Relay bus bar
7 External connection bus bar
8 Auxiliary base member
30 First circuit
31 Routing board
32 Bus bar (first bus bar)
33 First electronic component
34 Connection component
35 Base plate (base member)
36 Flat surface portion
37 Claw portion
40 Second circuit
41 First cover
41q Opening
42 Bus bar (second bus bar)
42A Bus bar
43 Second electronic component
45 Lock portion
45AR Arm portion
45PR Protrusion
46 Second cover
46q Opening
47 Fourth connection portion
48 Third extension portion
49 Signal connector
51 Support portion (heat transfer portion)
51s Support surface
52 Peripheral wall
53 First holding portion
53RS Recess
54 Second holding portion
61 First connection portion
62 Second connection portion
62s Flat surface
62h Fastening hole
63 First extension portion (extension portion)
64 Third connection portion
65 Second extension portion
71 Fifth connection portion
72 Sixth connection portion
73 Fourth extension portion
91 Insulating sheet
91A First insulating sheet
91B Second insulating sheet
92 Heat transfer member
92A First heat transfer member
92B Second heat transfer member
98 Cooler
101 Electrical connection unit
105 Heat radiation structure
151 Heat transfer portion
U Accommodation space

What is claimed is:

1. An electrical connection unit comprising:
a heat transfer portion;
a first circuit including a bus bar and a first electronic component electrically connected to the bus bar, the a first circuit being disposed on a first side in a first direction with respect to the heat transfer portion; and
a second circuit including a second electronic component and disposed on a second side in the first direction with respect to the heat transfer portion.

2. The electrical connection unit according to claim 1, wherein
the second electronic component has a lower heat resistant temperature than a heat resistant temperature of the first electronic component.

3. The electrical connection unit according to claim 1, wherein
the heat transfer portion contains a metal.

4. The electrical connection unit according to claim 1, wherein
the heat transfer portion supports the second circuit.

5. The electrical connection unit according to claim 1, further comprising a relay bus bar that includes a first connection portion electrically connected to the first circuit, a second connection portion electrically connected to the second circuit, and an extension portion extending between the first connection portion and the second connection portion.

6. The electrical connection unit according to claim 1, wherein
the first electronic component includes a relay.

7. The electrical connection unit according to claim 1, wherein
the second electronic component includes a sensor, a fuse, or a control circuit.

8. An electrical connection unit comprising:
a heat transfer portion;
a first circuit including a bus bar and a first electronic component electrically connected to the bus bar, the a first circuit being disposed on a first side in a first direction with respect to the heat transfer portion; and
a relay bus bar including a first connection portion electrically connected to the first circuit, a second connection portion capable of being electrically connected to a second circuit including a second electronic component, the second circuit being disposed on a second side in the first direction with respect to the heat transfer portion, and an extension portion extending between the first connection portion and the second connection portion.
